(19) United States
(12) Patent Application Publication
(10) Pub. No.: US 2009/0096027 A1
(43) Pub. Date: Apr. 16, 2009

(54) Power Semiconductor Device

(76) Inventors: Franz Hirler, Isen (DE); Hans-Joachim Schulze, Ottobrunn (DE)

Correspondence Address: COATS & BENNETT/INFINEON TECHNOLOGIES, 1400 CRESCENT GREEN, SUITE 300, CARY, NC, 27518, US

(21) Appl. No.: 11/870,093

(22) Filed: Oct. 10, 2007

(51) Int. Cl. H01L 23/62; H01L 21/82

(52) U.S. Cl. 257/356; 438/129; 257/E23.194; 257/E21.598

(57) ABSTRACT

A power semiconductor device comprising a first group of power transistor cells arranged in a first area of the power semiconductor device and a second group of power transistor cells arranged in a second area of the power semiconductor device. The first group of power transistor cells has an overall cell density different from that of the second group of power transistor cells such that the first and second groups of power transistor cells have different charge carrier densities.

### BACKGROUND

In the field of power semiconductor devices, and in particular in the field of insulated gate bipolar transistor (IGBT) devices, there exists a desire to increase the ruggedness of these devices. Destruction can occur to the devices when they are operated at high switching frequencies with high current and voltage slopes. Typical power semiconductor devices are subject to avalanche breakdown and latch-up which can occur when the devices are switched off.

Avalanche breakdown can occur when an electric field within a device is high enough to cause an avalanche multiplication of charge carriers. In a power semiconductor device, avalanche breakdown poses an upper limit on operating voltages as the avalanche multiplication of charge carriers can result in excessive current flow and destruction of the device.

Latch-up is caused by a parasitic PNPN structure that under certain bias conditions acts as a PNP transistor and an NPN transistor. When latch-up occurs, both transistors are conducting for as long as the PNPN structure is forward-biased and a high level of current flows through the structure.

Conventional methods to avoid destruction of power semiconductor devices such as IGBTs when switching the devices at high frequencies or with high voltage or current ramps include defining safe operating area (SOA) boundaries of the devices with respect to maximum dI/dt and dV/dt loads which cannot be exceeded. Currently the switching speeds must be reduced which can increase turn-off losses. Thus, the maximum reachable power in an application can be limited. While it may be desirable to limit dimensions of a p-emitter on a backside of a conventional IGBT in order to avoid the SOA restrictions, in practice this can be difficult to achieve. This is because the backside of a thin wafer IGBT would require additional processing due to the thin wafer.

Power semiconductor devices such as IGBTs can experience short-circuits which can result in an increase of current during a switch-off operation or while switching a load. In areas within the active regions such as within the cell areas of an IGBT, high current densities can occur which can lead to dynamic avalanche and latch-up beneath the neighboring source or emitter regions within the IGBT.

Thus, there exists a need for an improved power semiconductor structure within a semiconductor device.

### SUMMARY

One embodiment of the invention provides a power semiconductor device, comprising first and second groups of power transistor cells. The first group of power transistor cells is arranged in a first area of the power semiconductor device and the second group of power transistor cells is arranged in a second area of the power semiconductor device. The first group of power transistor cells has an overall cell density different from that of the second group of power transistor cells such that the first and second groups of power transistor cells have different charge carrier densities.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 shows an embodiment of a power semiconductor cell.

FIG. 2 shows an embodiment of a power semiconductor cell.

FIG. 3 shows an embodiment of a power semiconductor cell.

FIG. 4 shows a top view of an embodiment of a power semiconductor.

FIG. 4A shows a top view of an embodiment of two adjacent cells.

FIG. 5 shows a top view of an embodiment of a power semiconductor.

FIG. 6 shows a top view of an embodiment of a power semiconductor.

FIG. 7 shows partial areas of an embodiment of a power semiconductor.

FIG. 8 shows a sectional view of two cells of an embodiment of a power semiconductor.

FIG. 9 shows a sectional view of two cells of another embodiment of a power semiconductor.

FIGS. 10 and 11 show an embodiment of a cell and an adjacent gate runner and gate pad, respectively.

### DETAILED DESCRIPTION

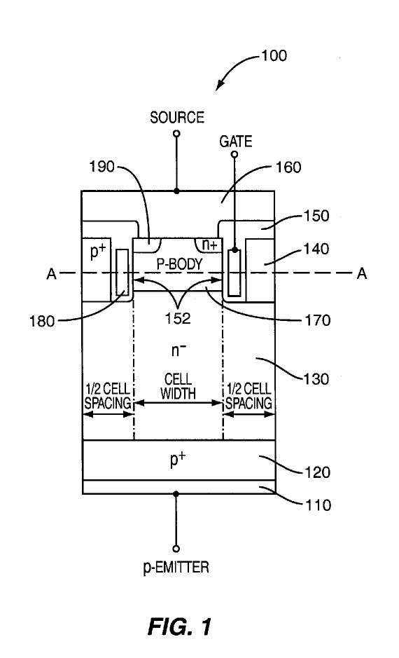

FIG. 1 shows an embodiment of a power semiconductor cell which is an IGBT cell 100 within a power semiconductor device. IGBT cell 100 comprises a p-doped substrate 120 and an n-doped epitaxial layer 130. Epitaxial layer 130 includes a p-doped region 140 that extends down from a top of epitaxial layer 130. A p-doped body 170 is separated from p-doped region 140 by an insulating layer 150 that is over the epitaxial layer 130. In one embodiment, the insulating layer 150 extends down into the epitaxial layer 130 and forms ring shaped side walls 152 for p-body island 170. In other embodiments, different shapes or dimensions of insulating layer 150 and p-body 170 can be used. In one embodiment, within the insulating side walls, a gate electrode 180 can be connected with an external terminal, for example, by means of a metal layer (not shown). In one embodiment, a ring shaped n-doped source region 190 can extend from the outer top surface of p-doped body 170 both vertically and horizontally into p-doped body 170. In the illustrated embodiment, a metal layer 160 forms a contact for the source of IGBT cell 100 and layer 110 forms a contact for the emitter of IGBT cell 100.

In the embodiment shown in FIG. 1, the cell proper is defined by the dotted lines which refer to the cell width defined by the p-body 170. In various embodiments, certain parameters of a cell can be varied to change the characteristics of the respective device. For example, a distance defined by drift zones between neighboring cells can be such a parameter. In various embodiments, a cell parameter can be the width of the cell itself, or the dimensions of gate 180, such as a width or depth of gate 180. In different embodiments, the parameter of the cell may be defined differently. If the body 170 is used to define the cell, the distance to the next cell as defined by the drift zone can be designed to be ½ of a cell width. However, in other embodiments, other definitions of what constitutes a cell may apply. For example, a cell could be defined by the width of the body 170 plus one-half of the distances to the neighboring p-body regions. In this example, FIG. 1 would represent a cell. The cell parameter “distance” would then be the distance between the centers of two neighboring cells.

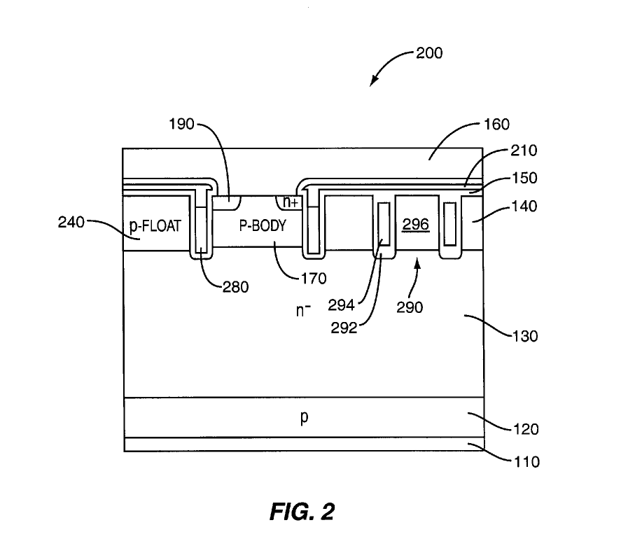

FIG. 2 shows an embodiment of a power semiconductor cell which is an IGBT cell 200. In this embodiment, a contact structure 210 forms a layer within the insulation region 150 and is connected to an upper end of gate electrode 280. In other embodiments, contact structure 210 such as a metal layer can connect to other areas of gate electrode 280. One or more p-float areas 240 are contained within epitaxial layer 130 and reach down from a top of the epitaxial layer 130 into the epitaxial layer 130. The p-float areas 240 are insulated from the p-body 170 by insulation layer 150 which, for example, also insulates the gate electrodes 280 from the p-body 170. According to other embodiments, other structures may be used to connect to the gate electrodes 280.

According to another embodiment, the cell structure may further include additional dummy cells 290 as shown, for example, on the right side of p-body 170. An additional trench 292 comprises a floating gate 294 which surrounds dummy p-body 296.

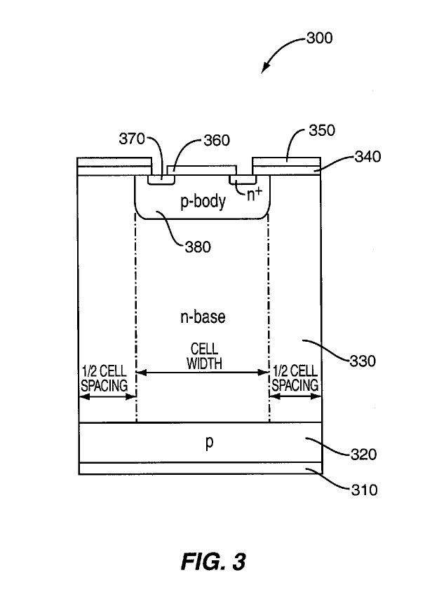

FIG. 3 shows an embodiment of a power semiconductor cell which is an IGBT formed on a p-doped substrate 320 forming the emitter of the power semiconductor. In this embodiment, an n-doped base epitaxial layer 330 is formed in which a transistor cell with a p-doped body 380 is arranged. The p-doped body region 380 reaches down from the top surface of the n-base layer 330 into the n-base layer 330 and comprises, in one embodiment, a ring shaped n⁺ source region 370 extending from a surface of p-doped body 380 down in to p-doped body 380. An insulating layer 340 is formed on top of the epitaxial layer 330 and comprises an opening into a region of the p-doped body 380. According to one embodiment, a contact metal layer 360 can be formed within the opening to provide for a source and a p-body 380 contact. According to some embodiments, on top of the insulation layer 340, a gate electrode 350 can be formed. In some embodiments, the n-base 330 can be formed by using n-doped starting material whereby a p-doped emitter 320 is formed by ion implantation into the backside of the wafer with a subsequent annealing or drive-in step. In one embodiment, the ion implantation is a boron ion implantation.

As stated before power semiconductor devices such as IGBTs can experience a short-circuit which will increase current during a switch-off operation or while switching a load. The short circuit areas within a power semiconductor carry a current during a turn-off phase or during dV/dt loads while blocking. If the density of these short circuit areas is lower in certain regions than in the rest of the device, then locally excessive current densities can occur when the device is subject to switching with high current or voltage slew rates. Locally excessive current densities can lead to latch up and dynamic avalanches. To reduce latch up and dynamic avalanches in a power semiconductor, charge carrier density is reduced in certain regions. Typical regions, in which no short circuits or a reduced density of short circuits are present, are, for example, within an IGBT structure the regions of the gate feeds, the gate pad, or the region of the edge termination. Other regions of a power semiconductor device may be critical.

According to different embodiments, charge carrier density can be reduced in these critical regions, in particular, by varying the cell structure in these critical regions. For example, according to an embodiment, a power semiconductor device may have a structure that varies the cell parameters for transistor cells that are arranged in close proximity to the edge of the device. As described above, a cell parameter in one embodiment can be the distance between two neighboring cells. In other embodiments, the parameter can be the width of a cell, the design of a gate electrode, the width of the drift zone, the additional provision of a barrier zone, or any other parameter that affects the charge carriers.

An inner cell area formed by the inner area of the device and an outer cell area formed by the edge area of the semiconductor device can be defined. The inner cell area of such a power semiconductor device comprises, for example, conventional IGBT cells or cells with predefined standard parameters. However, according to different embodiments, one or more parameters defining the cells of the outer area are varied to reduce charge carrier density in this area.

Charge carrier density can be reduced in the outer area according to one embodiment by reducing the cell distance. That is, charge carrier density is reduced by increasing cell density. With a reduction of the cell distance, charge carrier density in an IGBT cell becomes smaller. Thus, according to one embodiment, the cell distance is reduced in the critical areas as compared to the remaining non-critical areas. The area in which charge carrier density is reduced may extend, according to an embodiment, over 2-3 diffusion lengths. According to different embodiments, the reduction of the cell distances can be effected in a continuous manner or in a step-wise manner. According to other embodiments, other parameters of a cell may be varied to reduce charge carrier density.

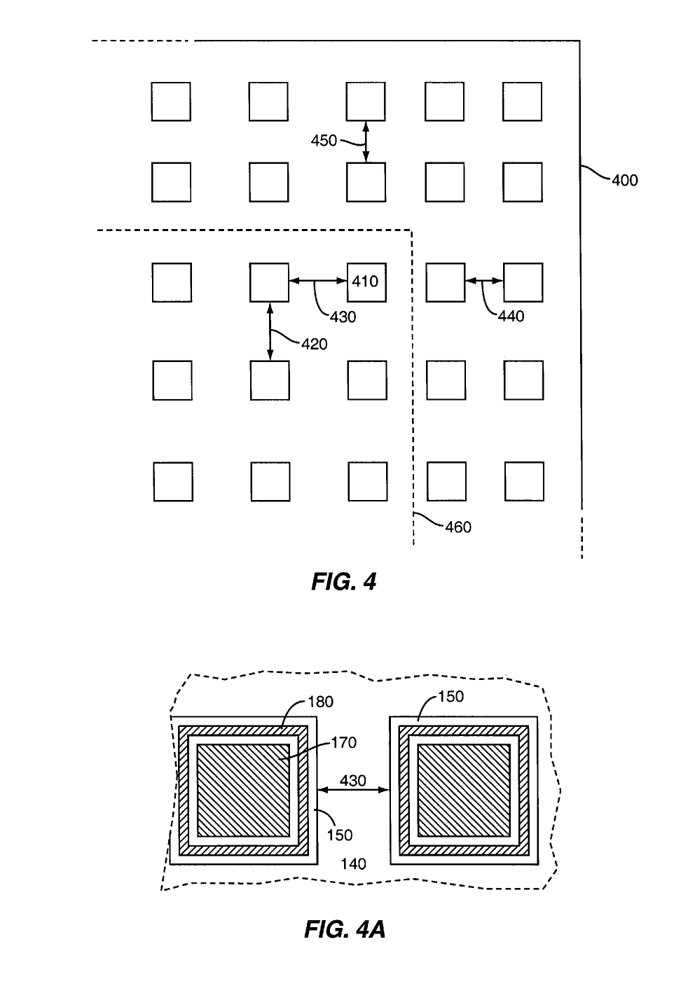

FIG. 4 shows a top view of an embodiment of a power semiconductor. A dotted line 460 divides the surface of a power semiconductor device into an inner non-critical area and an outer critical area and defines a ring that is arranged between an edge 400 and dotted line 460. In the illustrated embodiment, each square indicates a body 410 of an IGBT cell as shown, for example, in FIGS. 1-3. The cell array or matrix size is defined by x-axis distances 430 and y-axis distances 420.

FIG. 4A shows a top view of an embodiment of two adjacent cells. The top view is taken along line A-A as illustrated in FIG. 1. In the embodiment illustrated in FIG. 4A, gate 180 is disposed within insulating layer 150 and surrounds p-body 170. Each cell is contained within the p⁺ doped region 140. The term “cell” is used to define the inner area of a power semiconductor structure as, for example, defined by p-body 170 or p-body 170 and the surrounding gate 180. However, as stated above, other definitions of what constitutes a cell may apply and include more or less the area of a semiconductor device. According to an embodiment, the p-body 170 is connected to the source electrode. According to an embodiment, the IGBT with a planar gate 350, as illustrated in FIG. 3, has a cell that is defined by the p-body 380 region. The distances 420 and 430 indicate adjacent cell distance parameters that are approximately constant within the inner non-critical area of a power semiconductor device.

According to an embodiment, the cell distances indicated at 420 and 430 in FIGS. 4 and 4A can be the distance between the outer edges of respective p-bodies 170 of adjacent IGBT cells. However, the present application is not restricted to such a definition and other reference points can be used to define such a parameter. According to another embodiment, the distances 420 and 430 can include the drift zones between adjacent cells. In such a case, the width of a cell may be varied instead of the distance. According to another embodiment, the distance between the centers of two adjacent cells can be used in horizontal and/or vertical directions, or other equivalent locations within each cell can be used to define the distance between cells.

According to an embodiment, one or both of the distances between cells can be changed or varied for cells arranged within the outer perimeter of a power semiconductor, such as within the critical edge area of an IGBT. FIG. 4 shows that, for example, for cells arranged in the upper edge area, the y-axis distance 450 has been reduced with respect to “normal” distance 420. Similarly, the x-axis distance 440 for cells in the right edge area has been reduced with respect to “normal” distance 430. As shown in more detail in FIG. 4A, an enlargement of distance 430 will result in a lateral enlargement of the drift zone spacing between the cells defined by the now enlarged p⁺-doped region 140.

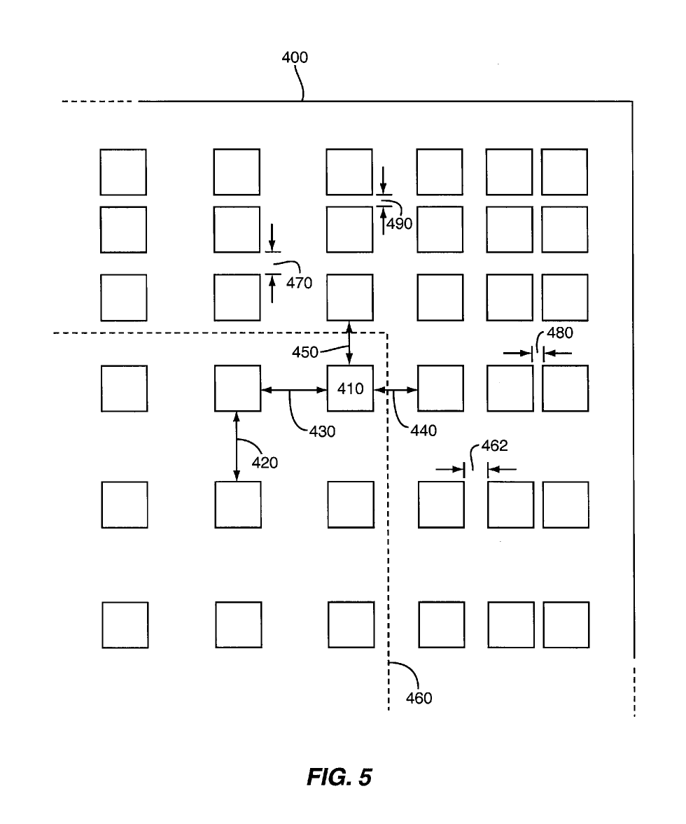

FIG. 5 shows a top view of an embodiment of a power semiconductor. As mentioned above, according to an embodiment, the reduction of the cell distance can also be decreased continuously or step-wise. FIG. 5 shows such a reduction. According to an embodiment, the distance on the x-axis is reduced in direction to the edge 400 of the device from a normal cell distance 430, to a reduced distance 440, then to a further reduced distance 462 and an even further reduced distance 480. Similarly, the distance on the y-axis can be equally be reduced as shown in FIG. 5 from a normal distance 420, to a reduced distance 450, then to a further reduced distance 470, and an even further reduced distance 490. According to various embodiments, within the corner areas of a chip, for example as shown in the upper right area of FIG. 5, both parameters such as the distance along the x-axis and the distance along the y-axis may vary.

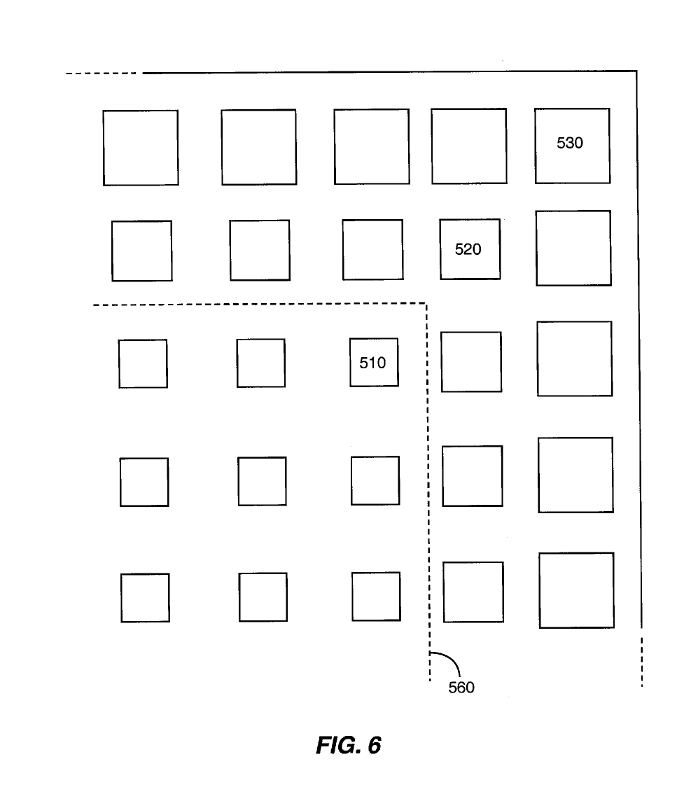

According to another embodiment, as for example shown in FIG. 6, the size of the p-body region can be increased to reduce the density of local charge carriers. To this end, FIG. 6 again shows dotted line 560 which separates an inner area with regular cells 510 and an outer or edge area with cells 520 and 530. According to an embodiment, edge area cells 520 have an increased p-body size as compared to cells 510. Cells 530 which are arranged more distant from inner cells 510 comprise an even more enlarged p-body as cells 520.

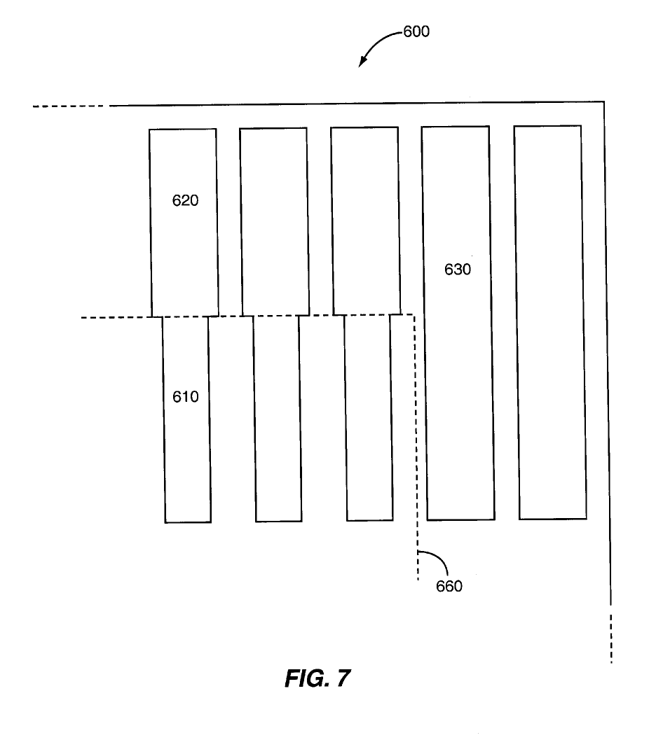

FIG. 7 shows partial areas of an embodiment of a power semiconductor. In this embodiment, the p-bodies of cells can be arranged in stripes. Here, according to an embodiment, the inner area cells 610 of a power semiconductor device 600 comprise stripes with a regular width. The width of the p-bodies is enlarged in the outer perimeter area which is defined by dotted line 660. P-body stripes 610 continue to the outer perimeter area beyond dotted line 660 and increase in width as shown at 620. According to an embodiment, stripes 630 which are entirely arranged within the outer perimeter area have a constant increased width. Alternatively, in yet another embodiment, the width of the stripes can be increased continuously or step-wise in direction to the edge of the device. In still another embodiment, the width of each of the stripes 620 or stripes 620 can be different than one or more of other ones of the stripes 620 or 630.

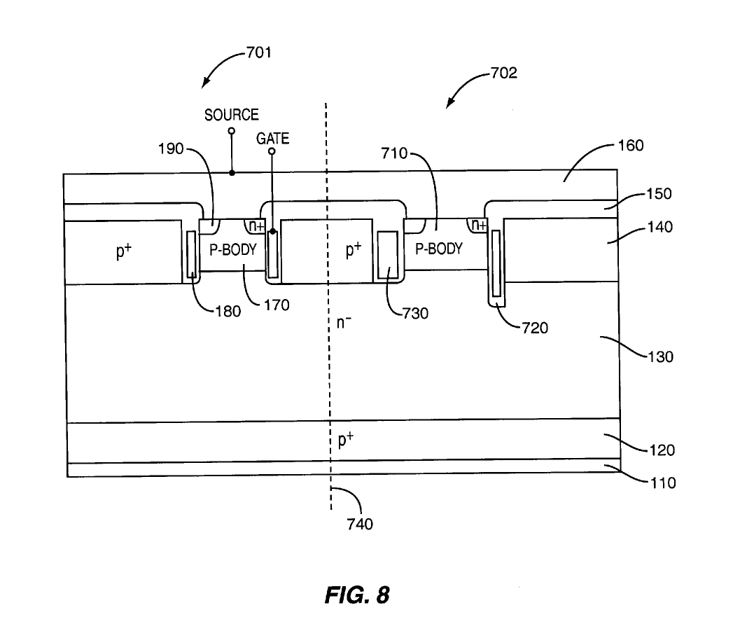

FIG. 8 shows a sectional view of two cells of an embodiment of a power semiconductor. A first cell 701 is located in the inner area of a power IGBT and a neighboring cell 702 is located in the critical edge area of the power IGBT. In this embodiment, the cell 701 is identical to cell 100 of FIG. 1. According to one embodiment, the neighboring cell 702 comprises a wider p-body 710. However, in another embodiment, the p-body may remain constant with respect to the respective size of cell 701. Furthermore, according to different embodiments, FIG. 8 shows two other embodiments of trench variations. FIG. 8 shows on the left side trench 730 which has an enlarged width with respect to cell 701 whereas on the right side, the depth of trench 720 has been increased. Of course, in other embodiments, both variations can be combined. In other embodiments, the trenches 720 and 730 can have any suitable width or depth.

In other embodiments, the so-called dummy cells shown in the right side of FIG. 2 can be introduced in less critical areas. Dummy cells do not comprise a source contact and may increase charge carrier density. In some embodiments, in critical areas such as within the edge regions, the dummy cells can be avoided to reduce charge carrier density.

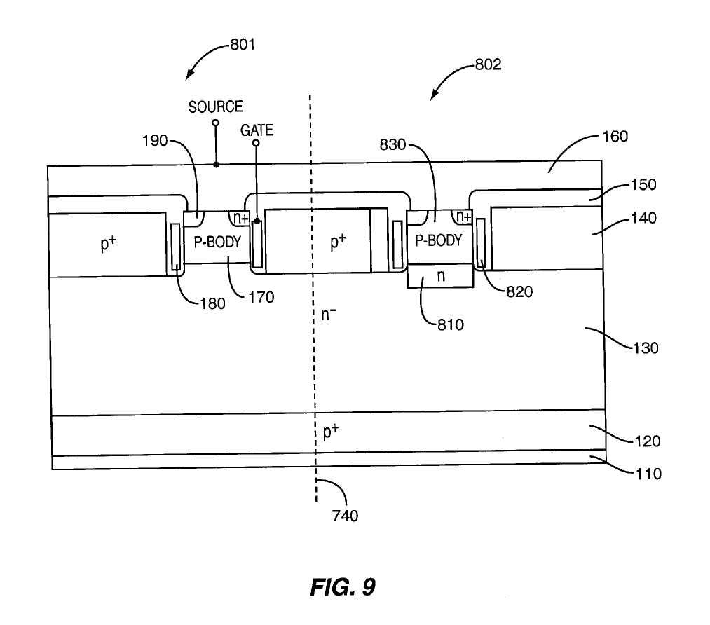

FIG. 9 shows a sectional view of two cells of another embodiment of a power semiconductor. In some embodiments, hole carriers can be locally introduced to provide a lateral variation of the charge carrier density. In these embodiments, hole barriers increase charge carrier density. In one embodiment, the hole barriers are created by forming a n-region 810 in proximity to or in front of the p-body within a cell. In the embodiment illustrated in FIG. 9, cell 801 is identical to cell 100 of FIG. 1 and cell 802 is similar to cell 801 with the exception that the n-doped area 810 is placed in proximity to or in front of the p-body 830. In this embodiment, neighboring cells 801 and 802 are divided by a dotted line 740 into an edge area (right side) and an inner area (left side). In critical device regions such as in the area of junction terminations, according to an embodiment, cell 801 is a more suitable design, whereas in less critical device regions, cell 802 can be implemented.

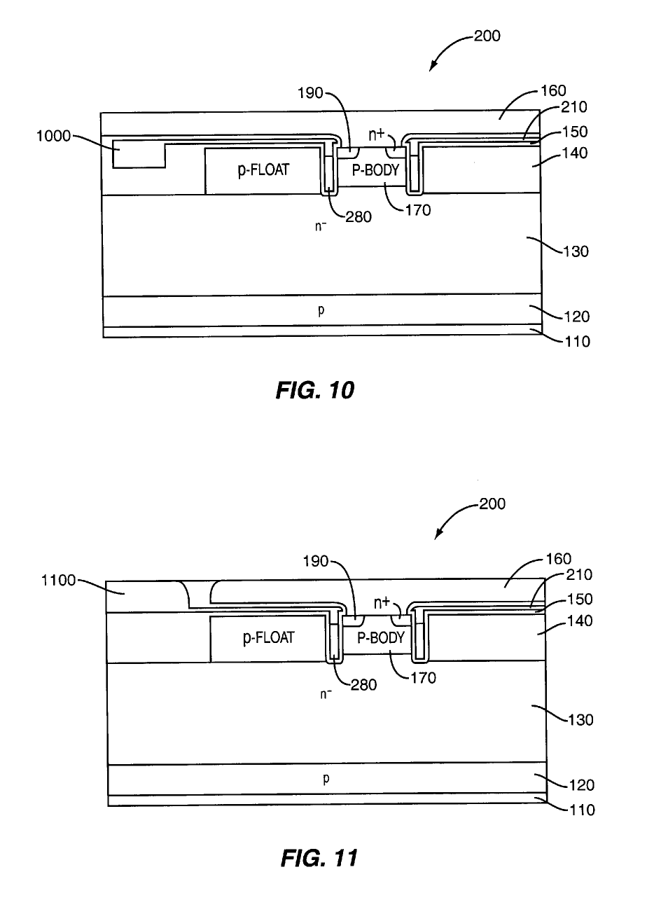

FIGS. 10 and 11 show an embodiment of a cell and an adjacent gate runner and gate pad, respectively. In various embodiments, variations may be defined in transition areas from the inner active area to outer edge areas. However, in some embodiments, these transition areas may also be between the active inner area and areas with gate pads or gate runners. FIG. 10, according to an embodiment, shows a gate runner 1000 arranged next to, for example, a cell 200 in such a transition area. In other embodiments, multiple gate runners 1000 may be arranged within a device to couple one or more gates 280 to one or more cells, up to and including all cells. FIG. 11 shows another embodiment with a gate pad 1100 coupled to the gate electrode 280 of a cell 200 of a power semiconductor device. Again, FIG. 11 only shows a single cell arranged in the transition area which is defined as the area comprising the gate pad 1100. In other embodiments, multiple gate pads 1100 may be arranged within a device to couple one or more gates 280 to one or more cells, up to and including all cells.

In other embodiments, any combination of the different embodiments described above is possible to reduce the charge carrier density in the critical areas. The increased density of charge carriers in non-critical areas can also be used for a so-called dynamic clamping function because in these areas with a respectively high enough charge carrier density, the dynamic avalanche may start earlier than in the critical areas, such as the edge area of an IGBT device. During a turn-off of the semiconductor device, the voltage rises and immediately thereafter the channel of the MOS transistor ceases injecting electrons into the base region and the device goes into a dynamic avalanche until it reaches a clamping voltage limit. According to an embodiment, the cells in the non-critical areas are designed such that the increased density of charge carriers allows for a clamping voltage limit that will not destroy the device. Therefore, the dynamic clamping function limits the voltage increase during turn-off of the device to a non-critical value.

The embodiments described and illustrated herein are not restricted to IGBTs. In other embodiments, other types of power semiconductors can be designed in accordance with these embodiments.

What is claimed is:

1. A power semiconductor device, comprising:
a first group of power transistor cells arranged in a first area of the power semiconductor device;
a second group of power transistor cells arranged in a second area of the power semiconductor device; and
wherein the first group of power transistor cells has an overall cell density different from that of the second group of power transistor cells such that the first and second groups of power transistor cells have different charge carrier densities.

2. The power semiconductor device according to claim 1, wherein a distance between neighboring power transistor cells arranged in the first area differs from a distance between neighboring power transistor cells arranged in the second area.

3. The power semiconductor device according to claim 1, wherein a size of the power transistor cells arranged in the first area differs from a size of the power transistor cells arranged in the second area.

4. The power semiconductor device according to claim 1, wherein the power transistor cells are arranged in stripes, and wherein a width of the stripes arranged in the first area differs from a width of the stripes arranged in the second area.

5. The power semiconductor device according to claim 1, further comprising dummy cells arranged in the first area, wherein the dummy cells are not coupled to a source contact and are configured to increase the charge carrier density in the first area with respect to the second area.

6. The power semiconductor device according to claim 1, wherein the power semiconductor device comprises a trench insulated gate bipolar transistor.

7. A method of fabricating a power semiconductor device, comprising:
providing a semiconductor substrate;
defining first and second areas of the semiconductor substrate; and
forming a first group of power transistor cells in the first area and a second group of power transistor cells in the second area, the first group of power transistor cells having an overall cell density different from that of the second group of power transistor cells such that the first and second groups of power transistor cells have different charge carrier densities.

8. The method according to claim 7, wherein forming the first and second groups of power transistor cells comprises forming neighboring power transistor cells in the first area at a distance different than that between neighboring power transistor cells in the second area.

9. The method according to claim 7, wherein forming the first and second groups of power transistor cells comprises sizing the power transistor cells in the first area differently than the power transistor cells in the second area.

10. The method according to claim 7, wherein forming the first and second groups of power transistor cells comprises forming the first and second groups of power transistor cells in stripes, wherein a width of the stripes formed in the first area differs from a width of the stripes formed in the second area.

11. The method according to claim 7, further comprising forming dummy cells in the first area, wherein the dummy cells are not coupled to a source contact and are configured to increase the charge carrier density in the first area with respect to the second area.

12. A power semiconductor device, comprising cells arranged within a first area and a second area of the power semiconductor device, wherein at least one parameter of the cells is varied for one or more of the cells in the second area with respect to one or more of the cells in the first area to reduce charge carrier density in the second area with respect to the first area.

13. The semiconductor device according to claim 12, wherein the second area is a transition area that extends from the one or more cells in the first area to one or more of a termination area, a gate pad or a gate runner.

14. The semiconductor device according to claim 12, further comprising a gate runner arranged adjacent to at least one of the one or more cells in the second area and coupled to a gate of the at least one of the one or more cells.

15. The semiconductor device according to claim 12, wherein the at least one parameter is a distance between adjacent cells, and wherein the distance in a direction along an x-axis or along a y-axis is smaller within the second area than within the first area.

16. The semiconductor device according to claim 12, wherein the at least one parameter is a size of a p-doped body of a power transistor cell, and wherein the size of the one or more cells in the second area is larger than the size of the one or more cells in the first area.

17. The semiconductor device according to claim 12, wherein the at least one parameter is a width of a p-doped body stripe of a power transistor cell, and wherein the width of the one or more cells in the second area is larger than the width of the one or more cells in the first area.

18. The semiconductor device according to claim 12, wherein the power semiconductor device comprises a trench insulated gate bipolar transistor, and wherein the at least one parameter is a width or depth of a trench of the trench insulated gate bipolar transistor.

19. A method of manufacturing a power semiconductor device, comprising:
providing a semiconductor substrate;
defining a first area and a second area of the semiconductor substrate; and
forming power transistor cells in the first and second areas, wherein at least one parameter of the cells within the second area is varied with respect to the cells in the first area to reduce charge carrier density in the second area.

20. The method according to claim 19, further comprising forming a gate runner adjacent to one or more cells within the second area and coupled with a gate in each of the one or more cells.

21. The method according to claim 19, wherein the at least one parameter is a distance between adjacent cells, and wherein the distance in a direction along an x-axis or along a y-axis is smaller within the second area than within the first area.

22. The method according to claim 19, wherein the at least one parameter is a size of a p-doped body of a power transistor cell, wherein the size of one or more cells in the second area is larger than the size of one or more cells in the first area.

23. The method according to claim 19, wherein the at least one parameter is a width of a p-doped body stripe of a power transistor cell, and wherein the width of the one or more cells in the second area is larger than the width of the one or more cells in the first area.

24. The method according to claim 19, further comprising forming a hole barrier in one or more of the cells within the first area.

25. A method of using a power semiconductor device, comprising:
providing a semiconductor substrate that comprises a first area and a second area, wherein the first area comprises a first cell structure and the second area comprises a second cell structure, and wherein the first cell structure is configured to provide an increased density of charge carriers in comparison to the second cell structure when the power semiconductor device is in an on-state; and
switching the power semiconductor device into the on-state, wherein the increased density of charge carriers enables a dynamic clamping of the power semiconductor device.
